(19) United States
(12) Patent Application Publication
(10) Pub. No.: US 2008/0203411 A1
(43) Pub. Date: Aug. 28, 2008

(54) Direct attachment of optically-active device to optical element

(76) Inventor: Hing Wah Chan, San Jose, CA (US)

Correspondence Address: BUCKLEY, MASCHOFF & TALWALKAR LLC, 50 LOCUST AVENUE, NEW CANAAN, CT, 06840, US

(21) Appl. No.: 11/711,274

(22) Filed: Feb. 27, 2007

(51) Int. Cl. H01L 33/00; H01L 31/0232; H01L 31/18

(52) U.S. Cl. 257/98; 257/432; 438/27; 438/65; 257/E31.127; 257/E33.071

(57) ABSTRACT

A system may include biasing of a substantially planar surface of an optically-active semiconductor device against a substantially planar surface of an optical element, and bonding of the substantially planar surface of the optically-active semiconductor device to the substantially planar surface of the optical element.

### BACKGROUND

1. Field

Some embodiments generally relate to the conversion of solar radiation to electrical energy. More specifically, embodiments may relate to systems to improve the efficiency of manufacture and/or operation of solar radiation collectors.

2. Brief Description

A concentrating solar radiation collector may convert received solar radiation (i.e., sunlight) into a concentrated beam and direct the concentrated beam onto a small photovoltaic cell. The cell, in turn, converts the photons of the received beam into electrical current.

Prior U.S. patent application Ser. No. 11/110,611 describes several types of concentrating solar collectors. As described therein, a photovoltaic cell may be mounted to concentrating optics and electrical contacts of a solar collector using a clear adhesive (e.g., silicone) and wire bonds, respectively. A photovoltaic cell may alternatively be connected to optics by clear underfill material and to electrical contacts by flip-chip (i.e., solder ball) interconnects.

Light concentrated by the above-mentioned concentrating solar collectors must pass through the clear interfacial material prior to reception by the photovoltaic cell. These collectors are therefore susceptible to Fresnel loss and/or to yellowing of the material. Either of these phenomena can reduce the efficiency with which the collectors convert received solar radiation to electricity. Additionally, wire bonding and solder ball reflow require several intermediate steps that may decrease the efficiency and increase the cost of manufacturing.

What is needed is a system to couple an optically-active semiconductor device to an optical element that addresses one or more of the foregoing and/or other existing concerns.

### SUMMARY

To address at least the foregoing, some aspects provide a method, means and/or process steps to bias a substantially planar surface of an optically-active semiconductor device against a substantially planar surface of an optical element, and to bond the substantially planar surface of the optically-active semiconductor device to the substantially planar surface of the optical element. In some aspects, the bonding comprises heating an interface between the substantially planar surface of the optically-active semiconductor device and the substantially planar surface of the optical element.

The optically-active semiconductor device may comprise a solar cell or a light-emitting diode in some aspects. According to some aspects, the substantially planar surface of the optically-active semiconductor device comprises a substantially light-transparent material and an electrical contact, and biasing the substantially planar surface of the optically-active semiconductor device against the substantially planar surface of the optical element comprises biasing the substantially light-transparent material against a substantially light-transparent portion of the optical element and biasing the electrical contact against a conductive portion of the optical element.

The optical element may comprise a surface opposite from the substantially planar surface of the optical element and to receive light. The optical element may concentrate the received light and direct the concentrated light toward the substantially planar surface of the optical element, and the concentrated light may pass through a substantially light-transparent material of the optically-active semiconductor device and be received by the semiconductor layer.

Some aspects may provide planarizing a surface of the optically-active semiconductor device to generate the substantially planar surface of the optically-active semiconductor device, and planarizing a surface of the optical element to generate the substantially planar surface of the optical element.

In some aspects, an apparatus includes an optically-active semiconductor device and an optical element, wherein a substantially planar surface of the optically-active semiconductor device is bonded to a substantially planar surface of the optical element.

According to further aspects, the optically-active semiconductor device comprises a semiconductor substrate comprising a majority of a first type of charge carrier, a semiconductor portion comprising a majority of a second type of charge carrier, a semiconductor layer disposed between the semiconductor substrate and the semiconductor portion to generate charge carriers of the first type and of the second type in response to received photons, a first metal contact, the semiconductor portion disposed between the first metal contact and the semiconductor layer, a second metal contact in contact with the semiconductor substrate and to receive charge carriers of the second type generated by the semiconductor layer, and a substantially light-transparent material, wherein the substantially planar surface of the optically-active semiconductor device comprises a first end of the first metal contact, a second end of the second metal contact, and the substantially light-transparent material.

Alternatively to the foregoing aspect, the optically-active semiconductor device may comprise a semiconductor substrate comprising a majority of a first type of charge carrier, a first semiconductor portion comprising a majority of a second type of charge carrier, a second semiconductor portion comprising a majority of the second type of charge carrier, a semiconductor layer disposed between the semiconductor substrate and the first and second semiconductor portions to generate charge carriers of the first type and of the second type in response to received photons, a first metal contact, the first semiconductor portion disposed between the first metal contact and the semiconductor layer, a second metal contact, the second semiconductor portion disposed between the second metal contact and the semiconductor layer, a third metal contact in contact with the semiconductor substrate and to receive charge carriers of the second type generated by the semiconductor layer, and a substantially light-transparent material, wherein the substantially planar surface of the optically-active semiconductor device comprises a first end of the first metal contact, a second end of the second metal contact, and the substantially light-transparent material.

The claims are not limited to the disclosed embodiments, however, as those in the art can readily adapt the description herein to create other embodiments and applications.

### BRIEF DESCRIPTION OF THE DRAWINGS

The construction and usage of embodiments will become readily apparent from consideration of the following specification as illustrated in the accompanying drawings, in which like reference numerals designate like parts.

FIG. 1 is a cross-sectional diagram of an apparatus comprising an optically-active semiconductor device and an optical element according to some embodiments.

FIG. 2 is a flow diagram of a method according to some embodiments.

FIG. 3 is a cross-sectional diagram illustrating a portion of the FIG. 2 method according to some embodiments.

FIG. 4 is a cross-sectional diagram of an apparatus comprising an optically-active semiconductor device and an optical element according to some embodiments.

FIG. 5 comprises cross-sectional diagrams of an optically-active semiconductor device and an optical element during a fabrication step according to some embodiments.

FIG. 6 comprises cross-sectional diagrams of an optically-active semiconductor device and an optical element during a fabrication step according to some embodiments.

FIG. 7 comprises cross-sectional diagrams of an optically-active semiconductor device and an optical element during a fabrication step according to some embodiments.

FIG. 8 is a cross-sectional diagram of an apparatus comprising an optically-active semiconductor device and an optical element according to some embodiments.

FIG. 9 is an exploded perspective view of an apparatus according to some embodiments.

FIG. 10 is a rear perspective view of the FIG. 9 apparatus according to some embodiments.

FIG. 11 is a cross-sectional side view illustrating operation of an apparatus according to some embodiments.

FIG. 12 is a close-up cross-sectional side view illustrating operation of an apparatus according to some embodiments.

FIG. 13 is a perspective view of an optical panel comprising an array of apparatuses according to some embodiments.

### DETAILED DESCRIPTION

The following description is provided to enable any person in the art to make and use the described embodiments and sets forth the best mode contemplated by for carrying out some embodiments. Various modifications, however, will remain readily apparent to those in the art.

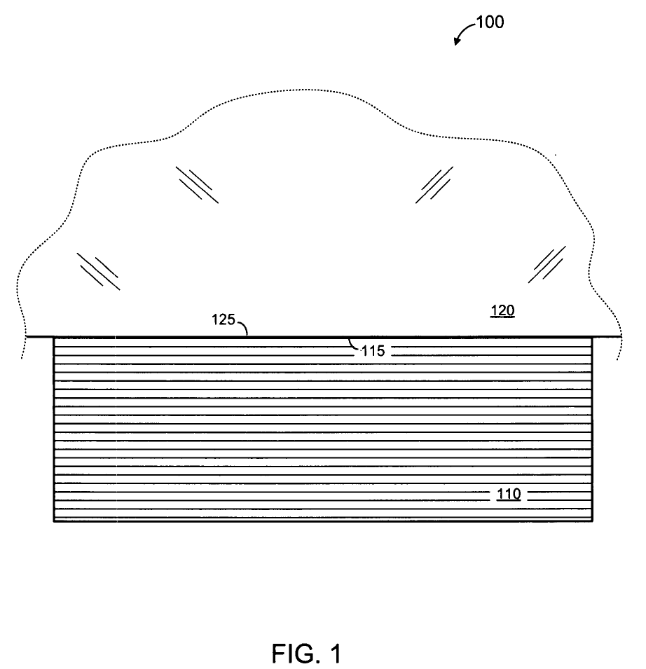

FIG. 1 is a cross-sectional side view of an apparatus according to some embodiments. Apparatus 100 comprises optically-active semiconductor device 110 and optical element 120. According to some embodiments, light passes between semiconductor device 110 and optical element 120 during operation.

Optically-active semiconductor device 110 may comprise a solar cell (e.g., a III-V cell, II-VI cell, etc.), a light-emitting diode, and/or any other semiconductor device capable of exhibiting photon-related behavior. For example, in a case that optically-active semiconductor device 110 comprises a solar cell, device 110 may receive photons from optical element 120 and generate electrical charge carriers in response thereto. Device 110 may comprise any number of active, dielectric and metallization layers, and may be fabricated using any suitable methods that are or become known.

Optically-active semiconductor device 110 comprises substantially planar surface 115. As will be described in detail below, substantially planar surface 115 may comprise a substantially light-transparent material and one or more electrical contacts in some embodiments. Substantially planar surface 115 is bonded to substantially planar surface 125 of optical element 120.

FIG. 1 shows only a portion of optical element 120 in order to illustrate that optical element 120 may exhibit any suitable shape or size. Optical element 120 may be configured to manipulate and/or pass desired wavelengths of light. According to some embodiments, optical element 120 is designed to pass wavelengths of light which correspond to the optical characteristics of device 110. Although optical element 120 appears homogenous, optical element 120 may comprise any number of disparate materials and/or elements (e.g., lenses, mirrors, etc.) according to some embodiments.

Substantially planar surface 125 of optical element 120 may comprise a substantially light-transparent portion and one or more conductive portions according to some embodiments. In a case that substantially planar surface 115 of semiconductor device 110 comprises a substantially light-transparent material and one or more electrical contacts, the substantially light-transparent portion of surface 125 may be bonded to the substantially light-transparent material of substantially planar surface 115 and the one or more conductive portions of surface 125 may be bonded to the one or more electrical contacts of substantially planar surface 115.

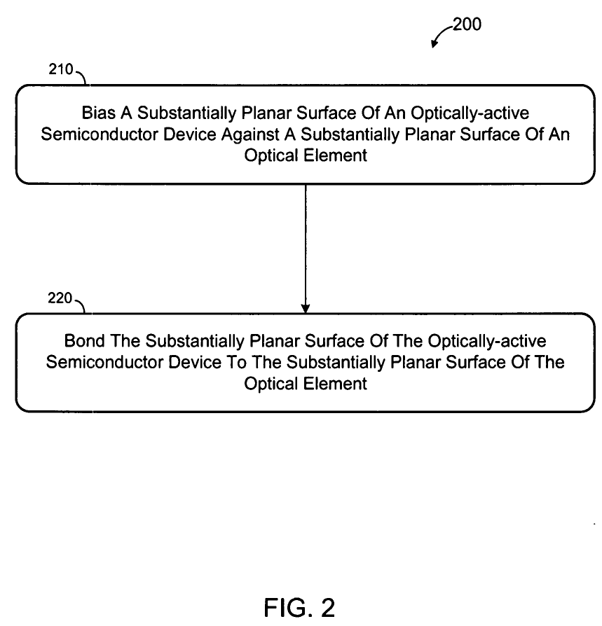

FIG. 2 is a flow diagram of process 200 according to some embodiments. Process 200 may be executed to fabricate an apparatus such as, but not limited to, apparatus 100 of FIG. 1. Process 200 may be performed by any combination of machine, hardware, software and manual means. Although process 200 operates on an optically-active semiconductor device and an optical element, process 200 may be executed by an entity other than the entity or entities which produced the semiconductor device or optical element.

Flow begins at 210, at which a substantially planar surface of an optically-active semiconductor device is biased against a substantially planar surface of an optical element. According to some embodiments, the substantially planar surface of the semiconductor device is aligned with the substantially planar surface of an optical element prior to 210. Such alignment may position elements of each planar surface adjacent to corresponding elements of the other planar surface. The alignment may proceed using any systems for aligning integrated circuit-sized features that are or become known.

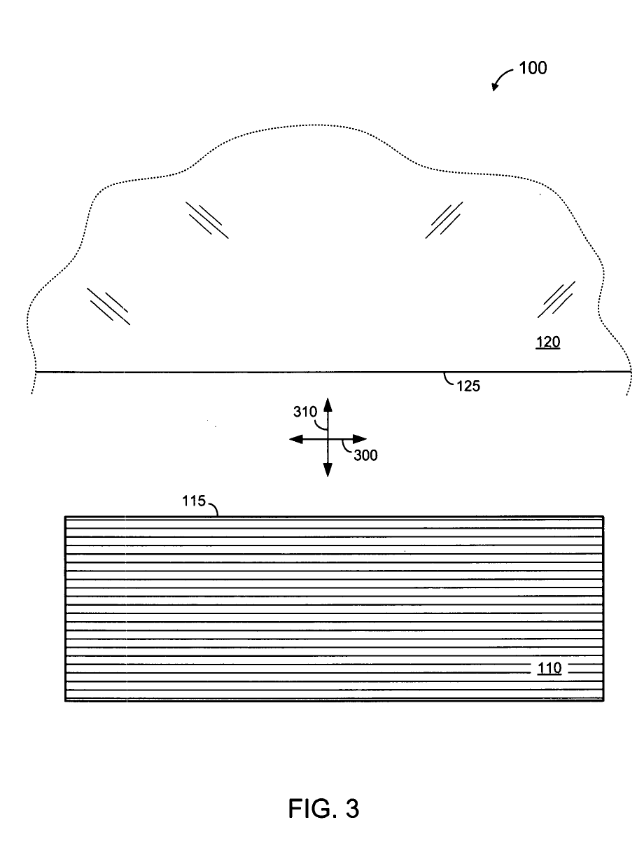

FIG. 3 is a cross-sectional side view of optically-active semiconductor device 110 and optical element 120 prior to 210 in some embodiments. Arrow 300 indicates relative movement of device 110 and element 120 in a plane perpendicular to the page during alignment, and arrow 310 indicates that one or both of device 110 and optical element 120 may be moved in order to bring device 110 and optical element 120 into contact with one another prior to biasing.

According to some embodiments, alignment prior to 210 ensures that a substantially light-transparent portion of surface 125 contacts a substantially light-transparent material of substantially planar surface 115 and one or more conductive portions of surface 125 contacts one or more electrical contacts of substantially planar surface 115.

Returning to 210, biasing the substantially planar surface of the optically-active semiconductor device against the substantially planar surface of the optical element may comprise applying pressure against the semiconductor device toward the optical element and/or applying pressure against the optical element toward the semiconductor device. Biasing at 210 may serve to form a temporary bond between the two substantially planar surfaces, and may be accompanied by heat in order to form such a temporary bond. A temporary bond may also be facilitated using suitable adhesives.

Next, at 220, the substantially planar surface of the optically-active semiconductor device is bonded to the substantially planar surface of the optical element. According to some embodiments of 220, heat is applied to an interface between the substantially planar surface of the optically-active semiconductor device and the substantially planar surface of the optical element. With reference to FIG. 1, the entire apparatus 100 may be heated in order to apply heat to the interface. In some embodiments, a heating element is applied to one or both of device 110 and element 120 in order to apply heat to the interface.

An amount of heat applied to the interface depends upon the composition of the substantially planar surface of the optically-active semiconductor device and the composition of the substantially planar surface of the optical element. The compositions will determine both the amount of heat that may be tolerated by the surfaces (i.e., thermal budget) as well as an amount of heat necessary to create a bond. Non-exhaustive examples of temperatures that have been deemed appropriate for bonding transparent dielectric material of an optically-active semiconductor device to transparent dielectric material of an optical element are ˜400° C. for glass frit and ˜275° C. benzocyclobutene.

The aligning, biasing and/or bonding of process 200 may proceed as described in “3D Packaging Via Advanced-Chip-To-Wafer (AC2W) Bonding Enables Hybrid System-In-Package (SIP) Integration”, S. Pargfrieder et al., Datacon Semiconductor Equipment GmbH, Radfeld, Austria. Unlike the present embodiments, however, the cited reference relates only to bonding a semiconductor chip to a semiconductor wafer.

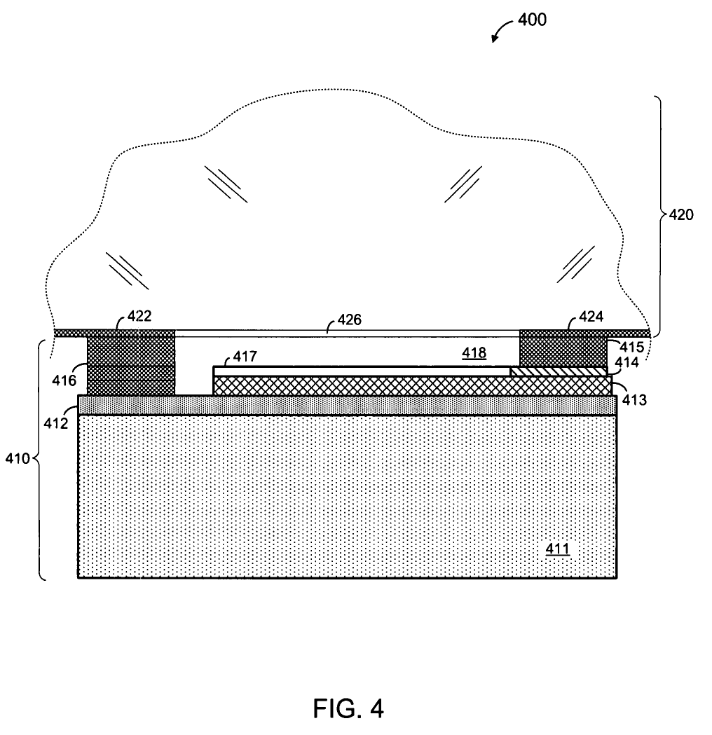

FIG. 4 is a cross-sectional side view of apparatus 400 according to some embodiments. Apparatus 400 comprises optically-active semiconductor device 410 and optical element 420. As shown, a substantially planar surface of device 410 is bonded to a substantially planar surface of optical element 420. Embodiments are not limited to the illustrated structure of optically-active semiconductor device 410.

Apparatus 400 may operate to receive light and to convert the received light to electrical current. Accordingly, optically-active semiconductor device 410 may comprise a solar cell. Device 410 includes semiconductor substrate 411 comprising a majority of a first type of charge carriers. For purposes of the present example, it will be assumed that substrate 411 comprises p+ Ge. Any other suitable substrate material may be used in conjunction with some embodiments, and the types of charge carriers associated therewith may be reversed (i.e., all p regions may be substituted for n regions and vice versa).

Semiconductor region 412 may comprise p++ Ge to improve current flow within device 410. Semiconductor layer 413 is capable of generating charge carriers (i.e., holes and electrons) in response to received photons. According to some embodiments, layer 413 comprises three distinct junctions deposited using any suitable method. According to some embodiments, the junctions are formed using molecular beam epitaxy and/or molecular organic chemical vapor deposition. The junctions may include a Ge junction, a GaAs junction, and a GaInP junction. Each junction exhibits a different band gap energy, which causes each junction to absorb photons of a particular range of energies.

Semiconductor portion 414 may comprise n++ GaAs and may support metal contact 415. Metal contact 415 may comprise any suitable metal contact, and may include an ohmic metal (e.g., Ag), a barrier contact (TiW), a solderable metal (Ni), and a passivation metal (e.g., Au). Metal contact 416 is coupled to semiconductor region 412 and exhibits a different polarity than metal contact 415 by virtue of the illustrated structure.

Optically-active semiconductor device 410 also includes anti-reflective coating 417 and substantially light-transparent material 418. Coating 417 and material 418 allow light from optical element 420 to reach semiconductor layer 413. Substantially light-transparent material 418 may comprise glass frit, benzocyclobutene or any other suitable material. The substantially planar surface of device 410 mentioned above may therefore comprise substantially light-transparent material 418, an end of metal contact 415, and an end of metal contact 416.

Optical element 420 may comprise any system to pass and/or otherwise manipulate light as desired. According to some embodiments, optical element 420 is designed to pass photons having energies which may be absorbed by semiconductor layer 413. The aforementioned substantially planar surface of optical element 420 includes substantially light-transparent material 426, an end of conductive portion 422, and an end of conductive portion 424. Substantially light-transparent material 426 may comprise any suitable material, and may be identical or different from substantially light-transparent material 418. In this regard, material 426 of optical element 420 is bonded to material 418 of device 410.

Conductive portion 422 is bonded to metal contact 416 and conductive portion 424 is bonded to metal contact 415. Accordingly, in operation, light may pass from optical element 420, through substantially light-transparent material 426, through substantially light-transparent material 418 and through anti-reflective coating 417 until being absorbed by semiconductor layer 413. Layer 413 generates charge carriers in response to the received light, which pass to metal contacts 415 and 416 and to corresponding ones of conductive portions 422 and 424. The charge carriers (i.e., electric current) are then conducted to the external circuitry to which conductive portions 422 and 424 are connected.

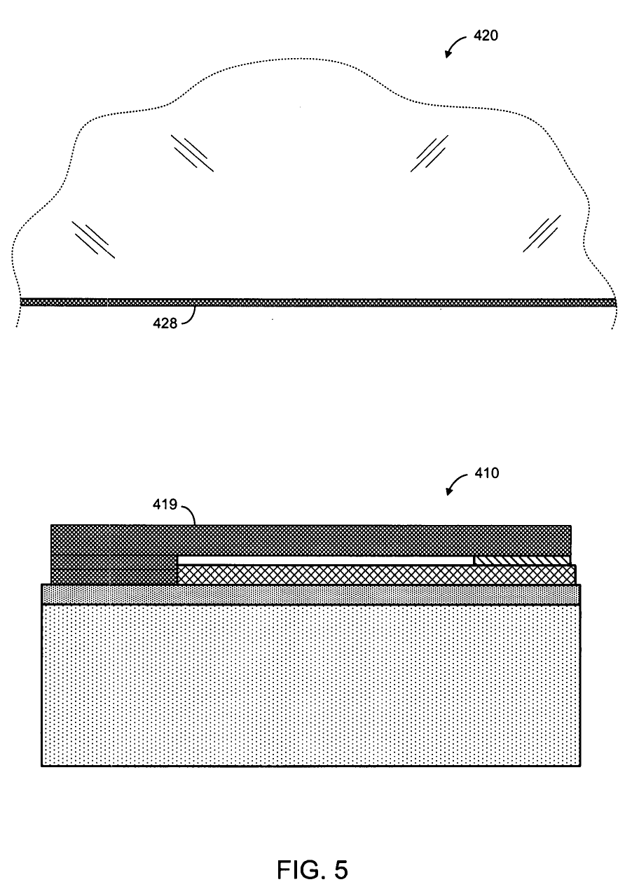

FIGS. 5 through 7 are cross-sectional side views to illustrate fabrication of planarized bonding surfaces according to some embodiments. To expedite the accompanying description, FIGS. 5 through 7 illustrate already-described optically-active semiconductor device 410 and optical element 420. The described fabrication is not, however, limited to device 410 and element 420.

FIG. 5 shows metallization layer 419 fabricated on optically-active device 410. Metallization layer 419 may comprise a solderable metal such as nickel and may be sputtered or otherwise deposited on device 410. Similarly, optical element 420 of FIG. 5 includes metallization layer 428. Metallization layer 428 may be deposited on optical element 420 using a same or different technique than that used to fabricate metallization layer 419.

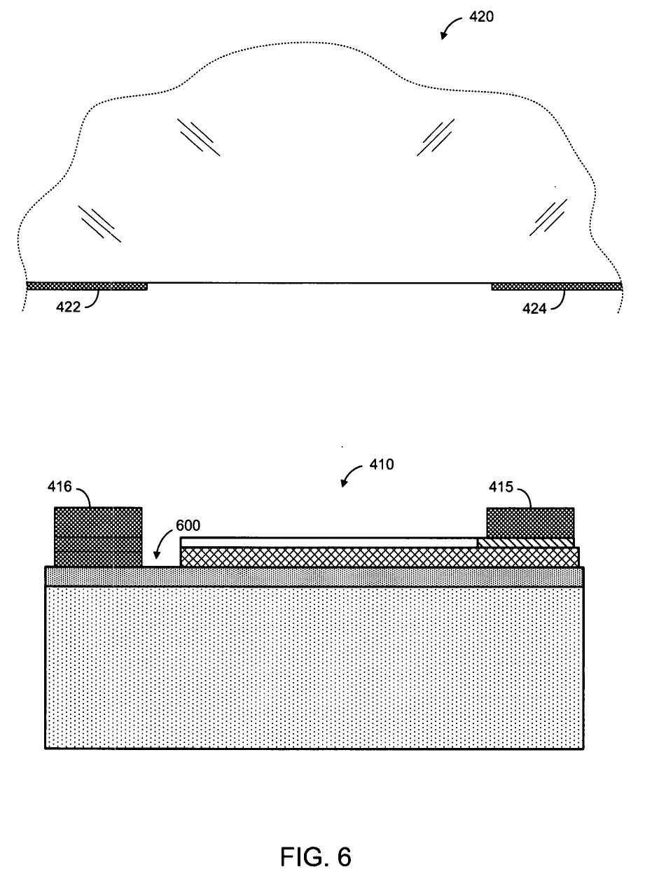

FIG. 6 illustrates optically-active semiconductor device 410 and optical element 420 after etching portions of metallization layers 419 and 428. According to some embodiments, photoresist is applied to metallization layers 419 and 428 and is patterned using masks or any other suitable systems. The photoresist is removed from certain areas of metallization layers 419 and 428 based on the pattern, and the exposed areas of metallization layers 419 and 428 are etched away. As a result, metal contacts 415 and 416 are formed, as are conductive portions 422 and 424. Two etching steps may be required to remove portions of metal contact 416 from area 600.

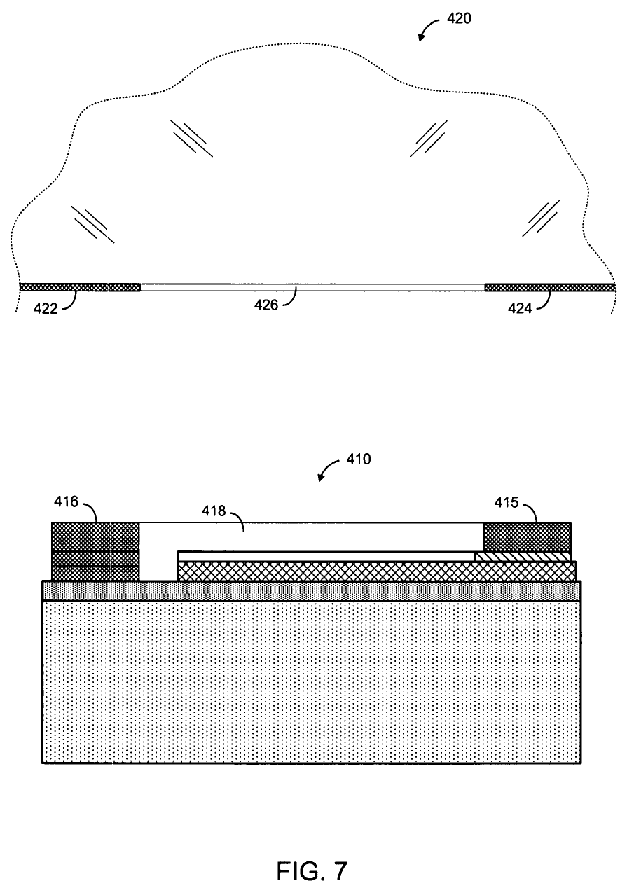

A substantially light-transparent material is deposited on semiconductor device 410 and optical element 420 as shown in FIG. 7. Substantially light-transparent material 426 of optical element 420 may comprise a first type of material and substantially light-transparent material 418 of optical element 410 may comprise a second type of material. However, using a same material may reduce losses or other undesirable effects that would otherwise occur at an interface between material 418 and material 426. According to some embodiments, the substantially light-transparent material comprises benzocyclobutene and is spun or sprayed onto device 410 and element 420.

Next, and as also depicted in FIG. 7, a surface including metal contacts 415 and 416 and material 418 is planarized. Similarly, a surface including conductive portions 422 and 424 and material 426 is also planarized. Planarization may proceed according to any suitable system that is or becomes known. In some embodiments, chemical-mechanical polishing is used to planarize the two surfaces. The substantially planar surface of optically-active semiconductor device 410 is then bonded to the substantially planar surface of optical element 420 as described with respect to process 200 and as illustrated in FIG. 4.

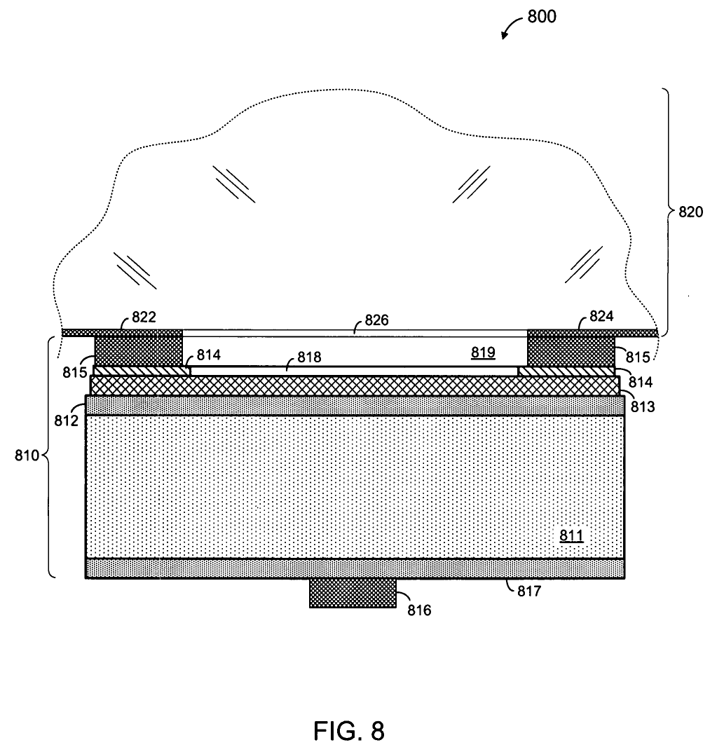

FIG. 8 is a cross-sectional side view of apparatus 800 according to some embodiments. Apparatus 800 comprises optically-active semiconductor device 810 and optical element 820. A substantially planar surface of device 810 is bonded to a substantially planar surface of optical element 820. Optical element 820 may be similar to optical element 420 described above.

Device 810 includes semiconductor substrate 811 comprising a majority of a first type of charge carriers. Substrate 811 comprises p+ Ge in some embodiments, but any other suitable substrate material may be used. Semiconductor region 812 may comprise p++ Ge to improve current flow within device 810, and semiconductor layer 813 is optically-active. More specifically, layer 813 is capable of generating charge carriers in response to received photons.

Semiconductor portions 814 may comprise n++ GaAs and may support metal contacts 815. Metal contact 816 is coupled to semiconductor region 817 comprising p++ Ge. Metal contact 816 exhibits a different polarity than metal contacts 815 by virtue of the illustrated structure.

Optically-active semiconductor device 810 also includes anti-reflective coating 818 and substantially light-transparent material 819. Coating 818 and material 819 allow light from optical element 820 to reach semiconductor layer 813. Substantially light-transparent material 818 may comprise glass frit, benzocyclobutene or any other suitable material. The substantially planar surface of device 810 mentioned above may therefore comprise substantially light-transparent material 818 and ends of metal contacts 815.

As shown, conductive portions 822 and 824 are bonded to metal contacts 815. Accordingly, conductive portions 822 and 824 likely exhibit a same polarity. In order for current to flow during operation, metal contact 816 may be connected to a conductive element of external circuitry that exhibits an opposite polarity and that provides an electrical path to metal contacts 815.

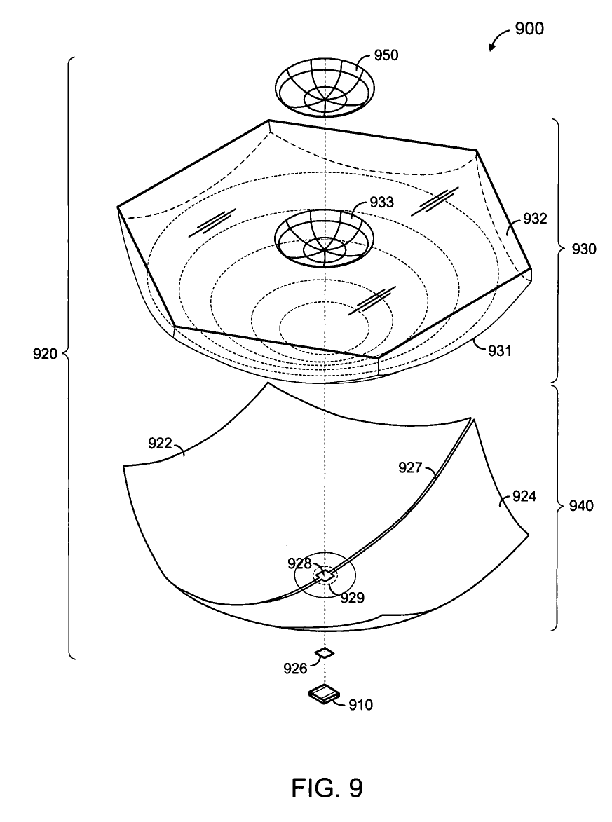

FIG. 9 is an exploded perspective view showing concentrating solar collector 900 according to some embodiments. Concentrating solar collector 900 includes photovoltaic cell 910 and optical element 920, which in turn includes substantially light-transparent material 926, substantially light-transparent core 930, primary mirror 940 and secondary mirror 950. As described with respect to previous embodiments, a substantially planar surface of photovoltaic cell 910 is bonded to a substantially planar surface of optical element 920.

Core 930 includes relatively large convex surface 931, substantially flat aperture surface 932, and relatively small concave surface 933. Primary mirror 940 and secondary mirror 950 are formed on convex surface 931 and concave surface 933, respectively. An upper periphery of optical element 920 includes six contiguous facets. This six-sided arrangement may facilitate the formation of large arrays of concentrating solar collectors 900 in a space-efficient manner.

In some embodiments, core 930 is molded from low-iron glass using known methods. Core 930 may alternatively be formed from a single piece of clear plastic, or separate pieces may be glued or otherwise coupled together to form core 930.

Primary mirror 940 and secondary mirror 950 may be fabricated by sputtering or otherwise depositing a reflective mirror material (e.g., silver (Ag) or aluminum (Al)) directly onto convex surface 931 and concave surface 933. Primary mirror 940 includes conductive portion 922 disposed on a first half of convex surface 932, and conductive portion 924 disposed on a second half of convex surface 931. Gap 927 is defined between conductive portions 922 and 924 to facilitate electrical isolation thereof. Accordingly, conductive portions 922 and 924 of primary mirror 940 may create a conductive path for electrical current generated by photovoltaic cell 910. Conductive portions 922 and 924 may also, as described in above-mentioned U.S. patent application Ser. No. 11/110,611, electrically link photovoltaic cells of adjacent collectors in a concentrating solar collector array.

Primary mirror 940 also includes opening 928 within area 929. As described above with respect to other embodiments, opening 928 is filled with substantially light-transparent material 926 and area 929 is planarized during fabrication of optical element 920. A substantially planar surface of cell 910 may then be bonded to planarized area 929 as described above.

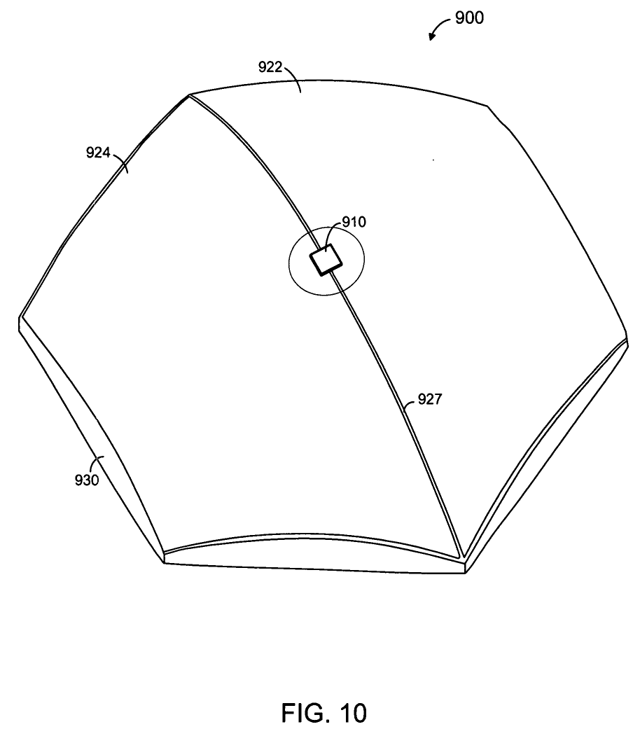

FIG. 10 is a rear perspective view of concentrating solar collector according to some embodiments. FIG. 10 clearly shows conductive portions 922 and 924 deposited on core 930 and separated by gap 927. Cell 910 may be encapsulated by a polymer or other suitable material after its substantially planar surface is bonded to a substantially planar surface of optical element 920.

Core 930, primary mirror 940 and secondary mirror 950 may possess any shapes suitable to achieve a desired region of light concentration, as will be described below. Those skilled in the art of optics will recognize that other conic or otherwise curved surfaces may be utilized to achieve the internal reflection necessary to transmit light to photovoltaic cell 910.

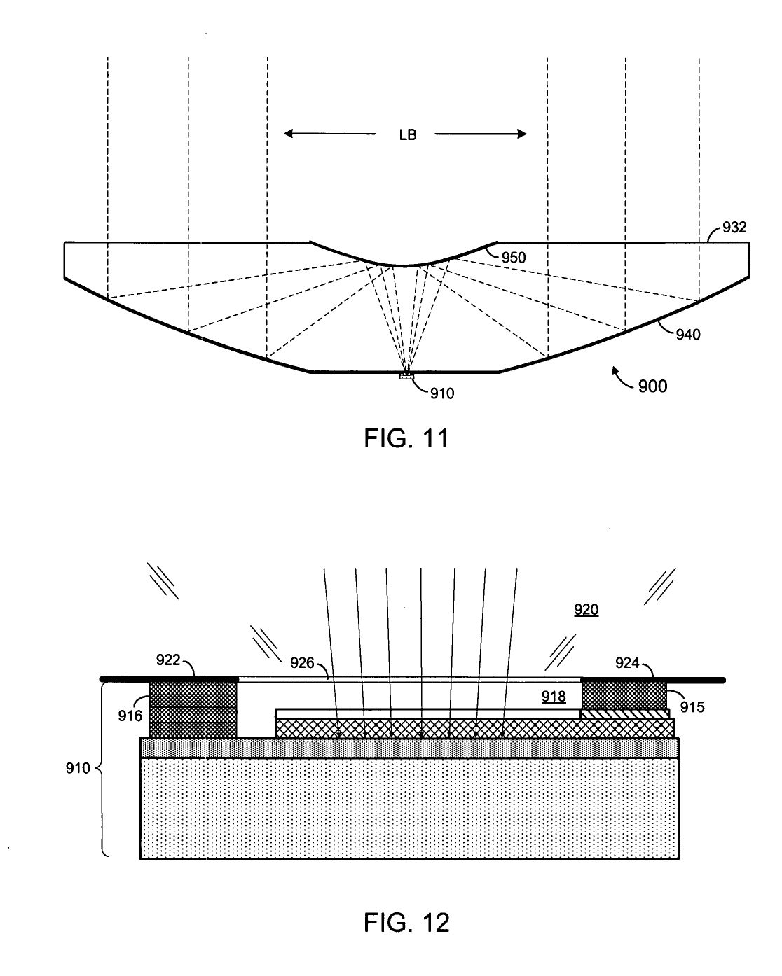

FIG. 11 is a side view showing concentrating solar collector 900 during operation according to some embodiments. As shown, light beams LB (e.g., solar rays) enter surface 932 and are concentrated by primary mirror 940 and secondary mirror 950 onto photovoltaic cell 910. FIG. 12 is a cross-sectional side view showing reception of the concentrated light by photovoltaic cell 910. As also shown in FIG. 12, optical element 920 comprises a substantially planar surface including conductive portions 922 and 924 and substantially light-transparent material 926. Semiconductor device 910 also includes a substantially planar surface composed of metal contacts 915 and 916 and substantially light-transparent material 918.

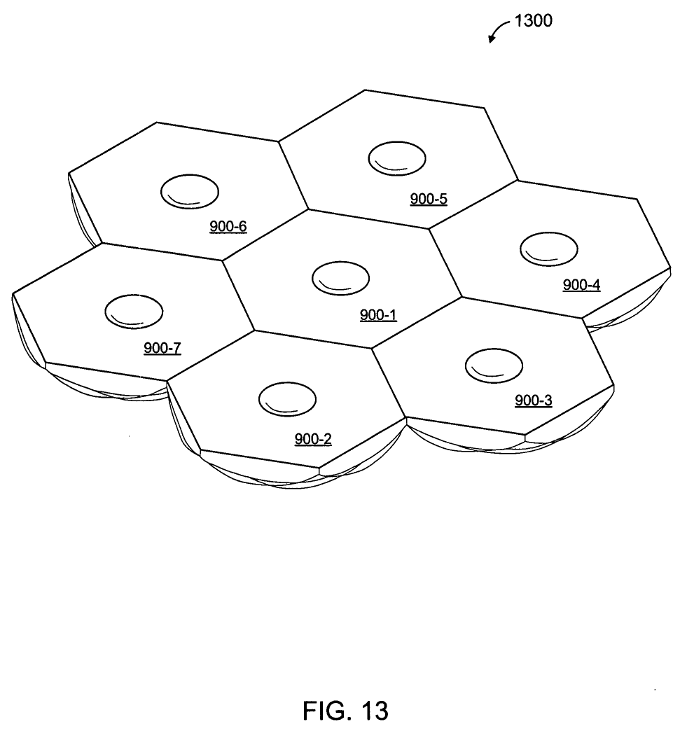

FIG. 13 is a perspective view showing a solid, light-transparent optical panel 1300 according to some embodiments. Optical panel 1300 comprises an integrated array of concentrating solar collectors 900-1 to 900-7 arranged in a honeycomb pattern. Each of collectors 900-1 to 900-7 is substantially identical to optical element 900 described above. As such, each of collectors 900-1 to 900-7 includes an optically-active semiconductor device and an optical element. Moreover, a substantially planar surface of each optically-active semiconductor device is bonded to a substantially planar surface of each optical element.

The several embodiments described herein are solely for the purpose of illustration. Embodiments may include any currently or hereafter-known versions of the elements described herein. Therefore, persons skilled in the art will recognize from this description that other embodiments may be practiced with various modifications and alterations.

What is claimed is:

1. A method comprising:
biasing a substantially planar surface of an optically-active semiconductor device against a substantially planar surface of an optical element; and
bonding the substantially planar surface of the optically-active semiconductor device to the substantially planar surface of the optical element.

2. A method according to claim 1, wherein bonding the substantially planar surface of the optically-active semiconductor device to the substantially planar surface of the optical element comprises:
heating an interface between the substantially planar surface of the optically-active semiconductor device and the substantially planar surface of the optical element.

3. A method according to claim 1, wherein the optically-active semiconductor device comprises a solar cell.

4. A method according to claim 3, wherein the optically-active semiconductor device comprises a III-V solar cell.

5. A method according to claim 3, wherein the optically-active semiconductor device comprises a II-VI solar cell.

6. A method according to claim 1, wherein the optically-active semiconductor device comprises a light-emitting diode.

7. A method according to claim 1, wherein the substantially planar surface of the optically-active semiconductor device comprises a substantially light-transparent material, and
wherein the substantially light-transparent material is in contact with a semiconductor layer of the optically-active semiconductor device to generate charge carriers in response to received photons.

8. A method according to claim 7, wherein biasing the substantially planar surface of the optically-active semiconductor device against the substantially planar surface of the optical element comprises:
biasing the substantially light-transparent material against a substantially light-transparent portion of the optical element.

9. A method according to claim 8, wherein the substantially planar surface of the optically-active semiconductor device comprises an electrical contact, and
wherein biasing the substantially planar surface of the optically-active semiconductor device against the substantially planar surface of the optical element further comprises:
biasing the electrical contact against a conductive portion of the optical element.

10. A method according to claim 7, wherein the substantially light-transparent material comprises glass frit.

11. A method according to claim 7, wherein the substantially light-transparent material comprises benzocyclobutene.

12. A method according to claim 7, wherein the substantially light-transparent material comprises silicone.

13. A method according to claim 7,
wherein the substantially light-transparent material comprises an anti-reflective coating.

14. A method according to claim 7,
wherein the optical element comprises a surface to receive light, the surface opposite from the substantially planar surface of the optical element,
wherein the optical element is to concentrate the received light and to direct the concentrated light toward the substantially planar surface of the optical element, and
wherein the concentrated light is to pass through the substantially light-transparent material of the optically-active semiconductor device and is to be received by the semiconductor layer.

15. A method according to claim 1, further comprising:
planarizing a surface of the optically-active semiconductor device to generate the substantially planar surface of the optically-active semiconductor device; and
planarizing a surface of the optical element to generate the substantially planar surface of the optical element.

16. An apparatus comprising:
an optically-active semiconductor device; and
an optical element,
wherein a substantially planar surface of the optically-active semiconductor device is bonded to a substantially planar surface of the optical element.

17. An apparatus according to claim 16, wherein the optically-active semiconductor device comprises a solar cell.

18. An apparatus according to claim 17, wherein the optically-active semiconductor device comprises a III-V solar cell.

19. An apparatus according to claim 17, wherein the optically-active semiconductor device comprises a II-VI solar cell.

20. An apparatus according to claim 16, wherein the optically-active semiconductor device comprises a light-emitting diode.

21. An apparatus according to claim 16, wherein the substantially planar surface of the optically-active semiconductor device comprises a substantially light-transparent material, and
wherein the substantially light-transparent material is in contact with a semiconductor layer of the optically-active semiconductor device to generate charge carriers in response to received photons.

22. An apparatus according to claim 21, wherein the substantially planar surface of the optical element comprises a substantially light-transparent portion, and
wherein the substantially light-transparent material of the optically-active semiconductor device is in contact with the substantially light-transparent portion of the optical element.

23. An apparatus according to claim 22, wherein the substantially planar surface of the optical element comprises a conductive portion,
wherein the substantially planar surface of the optically-active semiconductor device comprises an electrical contact, and
wherein the electrical contact of the optically-active semiconductor device is in contact with the conductive portion of the optical element.

24. An apparatus according to claim 21, wherein the substantially light-transparent material comprises glass frit.

25. An apparatus according to claim 21, wherein the substantially light-transparent material comprises benzocyclobutene.

26. An apparatus according to claim 21,
wherein the substantially light-transparent material comprises an anti-reflective coating.

27. An apparatus according to claim 21,
wherein the optical element comprises a surface to receive light, the surface opposite from the substantially planar surface of the optical element,
wherein the optical element is to concentrate the received light and to direct the concentrated light toward the substantially planar surface of the optical element, and
wherein the concentrated light is to pass through the substantially light-transparent material of the optically-active semiconductor device and is to be received by the semiconductor layer.

28. An apparatus according to claim 16, wherein the optically-active semiconductor device comprises:
a semiconductor substrate comprising a majority of a first type of charge carrier;
a semiconductor portion comprising a majority of a second type of charge carrier;
a semiconductor layer disposed between the semiconductor substrate and the semiconductor portion to generate charge carriers of the first type and of the second type in response to received photons;
a first metal contact, the semiconductor portion disposed between the first metal contact and the semiconductor layer;
a second metal contact in contact with the semiconductor substrate and to receive charge carriers of the second type generated by the semiconductor layer; and
a substantially light-transparent material,
wherein the substantially planar surface of the optically-active semiconductor device comprises a first end of the first metal contact, a second end of the second metal contact, and the substantially light-transparent material.

29. An apparatus according to claim 16, wherein the optically-active semiconductor device comprises:
a semiconductor substrate comprising a majority of a first type of charge carrier;
a first semiconductor portion comprising a majority of a second type of charge carrier;
a second semiconductor portion comprising a majority of the second type of charge carrier;
a semiconductor layer disposed between the semiconductor substrate and the first and second semiconductor portions to generate charge carriers of the first type and of the second type in response to received photons;
a first metal contact, the first semiconductor portion disposed between the first metal contact and the semiconductor layer;
a second metal contact, the second semiconductor portion disposed between the second metal contact and the semiconductor layer;
a third metal contact in contact with the semiconductor substrate and to receive charge carriers of the second type generated by the semiconductor layer; and
a substantially light-transparent material,
wherein the substantially planar surface of the optically-active semiconductor device comprises a first end of the first metal contact, a second end of the second metal contact, and the substantially light-transparent material.
